(19) United States
(12) Patent Application Publication
(10) Pub. No.: US 2011/0241212 A1
(43) Pub. Date: Oct. 6, 2011

(54) STRESS LAYER STRUCTURE

(75) Inventors: Chin-Sheng YANG, Hsinchu (TW); Chih-Chien Liu, Taipei City (TW)

(73) Assignee: UNITED MICROELECTRONICS CORP., Hsinchu (TW)

(21) Appl. No.: 13/150,341

(22) Filed: Jun. 1, 2011

Related U.S. Application Data
(63) Continuation-in-part of application No. 11/695,761, filed on Apr. 3, 2007.

(51) Int. Cl. H01L 23/522

(52) U.S. Cl. 257/758; 257/E23.142

(57) ABSTRACT

A stress layer structure includes an active stress portion and a dummy stress portion, both formed of a stress material and disposed on the substrate. The active stress portion includes first and second active stress patterns in a region where active devices are formed. The first and second active stress patterns coverrespective active regions, and are separated from each other. The dummy stress portion includes a first dummy stress pattern formed directly on the substrate and disposed between and separated from the first and second active stress patterns.

### CROSS-REFERENCE TO RELATED APPLICATIONS

The present application is a continuation-in-part application claiming benefit from a parent U.S. patent application bearing a Ser. No. 11/695,761 and filed Apr. 3, 2007, contents of which are incorporated herein for reference.

### FIELD OF THE INVENTION

The present invention relates to a stress layer structure, and more particularly to a stress layer structure applied to a substrate with active and/or passive devices formed thereon for releasing undue stresses.

### BACKGROUND OF THE INVENTION

As technological progress leads semiconductor fabrication into the deep sub-micron era, the demand for increasing the driving current of an N-type metal oxide semiconductor (NMOS) transistor and a P-type metal oxide semiconductor (PMOS) transistor is currently on the rise. To be more specific, in the present technology of fabrication process involving a feature size below 65 nm, the effective improvement of the driving current of the NMOS and the PMOS greatly reduces time delay and raises the processing speed of the device.

In recent years, various proposals to increase the driving current of the device with use of an internal stress have been addressed in the industry. The most common solution is to form a stress layer on both the NMOS transistor and the PMOS transistor. As a tensile stress of the stress layer increases, the driving current at a channel region of the NMOS is then raised. Likewise, as a compressive stress of the stress layer increases, the driving current at the channel region of the PMOS is then raised.

For example, Kumagai et al. (U.S. Pub. No. 2004/0075148) discloses a semiconductor device including an n-channel field effect transistor and a p-channel field effect transistor, and tensile and compressive stress control films covering gate electrodes of the n-channel field effect transistor and the p-channel field effect transistor, respectively, thereby improving drain current in both the n-channel field effect transistor and the p-channel field effect transistor. Concretely, the semiconductor device includes a plurality of 2NAND circuits arranged in series in a repetitive pattern. That is, as shown in FIG. 1A, the device is configured by an area NM in which n-channel-type field effect transistors are continuously arranged by repeatedly arranging the p-channel-type field effect transistors P1 and P2 and the n-channel-type field effect transistors N1 and N2, and an area PM in which p-channel-type field effect transistors are repeated. A tensile stress control film 209 is continuously formed over the entire circuit layout other than the field enclosed by the active of the p-channel-type field effect transistor, in the longitudinal direction of the gate electrode of the transistor. Alternatively, as shown in FIG. 1B, no film is formed on the field area (shallow groove device separation) adjacent to the active of the p-channel-type field effect transistor and perpendicular to the drain current, and on the field area surrounding the active area of the n-channel-type field effect transistor in the compressive stress control film 209 covering the entire surface of the circuit layout. In both examples, the stress control film 209 covers the entire surface of the circuit layout.

However, the increase in the stress of the stress layer often brings about the fracture of the stress layer due to undue stresses. Simultaneously, particles are formed when the stress layer cracks. Moreover, the increase in the stress of the stress layer leads to peeling of the stress layer in a high stress region or at the corner of the stress layer. All of the defects presented above deteriorate the performance of the semiconductor devices and further decrease yield of products.

### SUMMARY OF THE INVENTION

Therefore, the present invention provides a stress layer structure with an undue stress releasing mechanism so as to prevent the stress layer from cracking, peeling off, or producing particles and thus improve yield of products.

The present invention relates to a stress layer structure formed on a substrate. The substrate includes a first region where active devices are formed and a second region where passive devices are formed. The stress layer structure includes an active stress portion formed of a stress material and disposed on the substrate, wherein the active stress portion includes first and second active stress patterns in the first region, which cover a first active region and a second active region, respectively, and are separated from each other; and a dummy stress portion formed of a stress material and disposed on the substrate, wherein the dummy stress portion includes at least one first dummy stress pattern in the first region, which is formed directly on the substrate and disposed between and separated from the first and second active stress patterns.

The present invention further relates to a stress layer structure formed on a substrate. The substrate includes a first region where active devices are formed and a second region where passive devices are formed. The stress layer structure includes an active stress portion formed of a stress material and disposed on the substrate, wherein the active stress portion includes a continuous active stress pattern in the first region, which covers at least one active region; and a dummy stress portion formed of a stress material and disposed on the substrate, wherein the dummy stress portion includes a continuous dummy stress pattern with a plurality of dummy openings therein in the second region.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic diagram illustrating the configuration of a tensile stress control film applied to a circuit layout according to prior art;

FIG. 1B is a schematic diagram illustrating the configuration of a compressive stress control film applied to a circuit layout according to prior art;

FIG. 2 is a top view schematically illustrating the configuration of a stress layer structure according to a first embodiment of the present invention;

FIG. 3 is a top view schematically illustrating the configuration of a stress layer structure according to a second embodiment of the present invention; and

FIG. 4 is a top view schematically illustrating the configuration of a stress layer structure according to a third embodiment of the present invention.

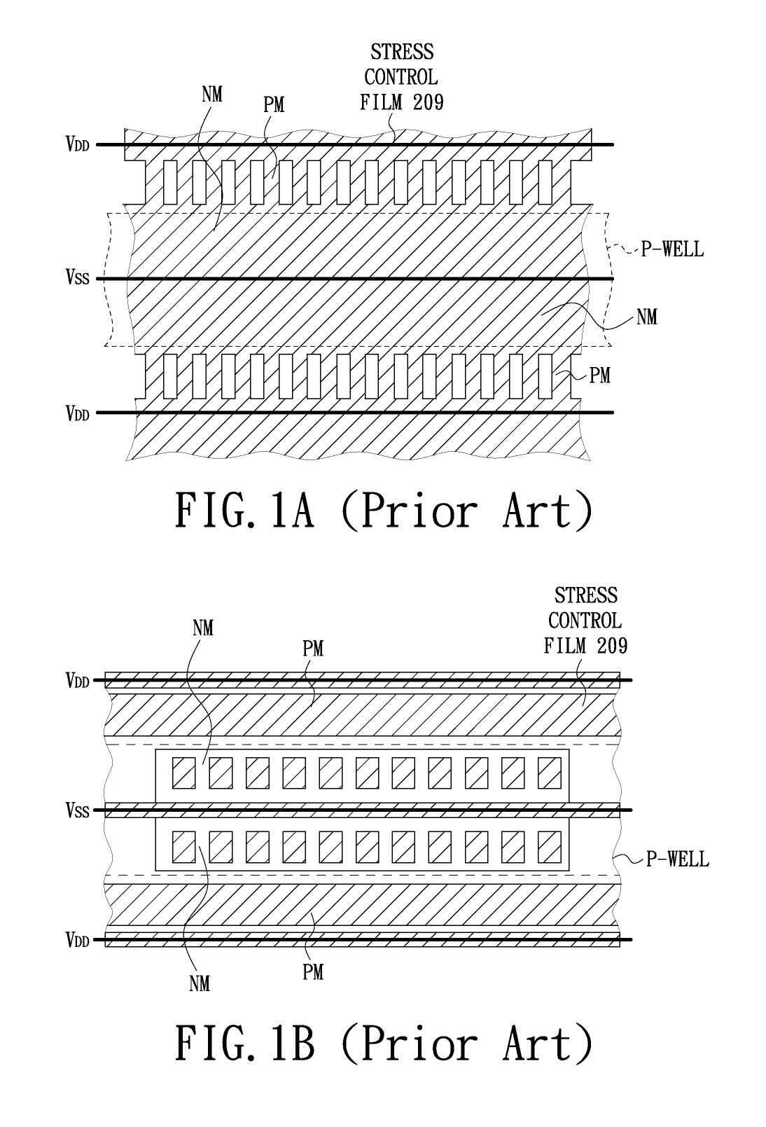

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

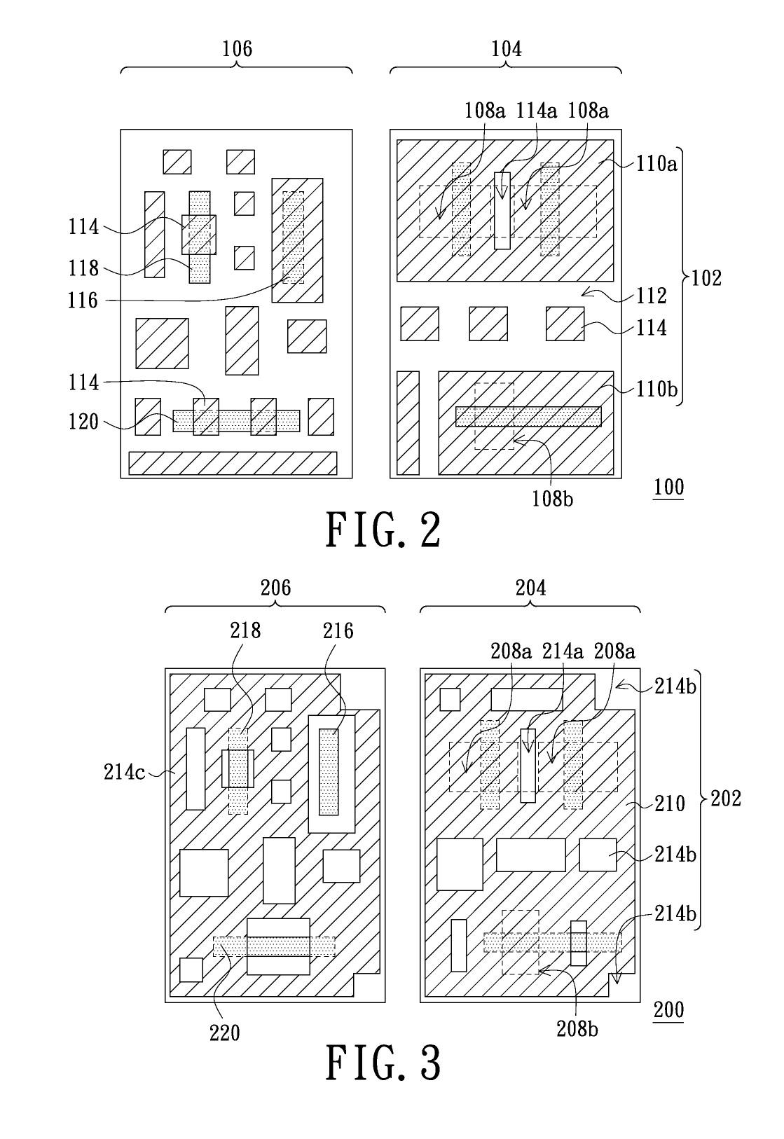

Referring to FIG. 2, a stress layer structure 102 is applied onto a substrate 100 according to the present invention. The stress layer structure 102 includes an active stress portion for raising stress, and a dummy stress portion for releasing undue stress as an effect of balance. The active stress portion includes stress patterns 110a and 110b covering active regions 108a and 108b in a first region 104, which require stress, and the dummy stress portion includes dummy stress patterns 114 formed directly on the substrate 100 and covering a portion 112 of the substrate 100 in the first region 104, where no circuit element is formed, and also formed on the substrate 100 in a second region 106. It is to be noted that the first region 104 is defined herein as a region where active devices such as MOS structures and isolation structure are disposed; while the second region 106 is defined as a region where some passive devices such as resistors are disposed on isolation structures. The dummy stress patterns 114 may further partially or completely cover specified structures, e.g. polysilicon conductive patterns/lines 116, 118 and 120, in the second region 106. On the substrate in both of the first and second regions 104 and 106, a variety of polysilicon patterns/lines are formed. For example, in the first region 104, an active device such as a MOS transistor is formed in an active region covered with a polysilicon pattern/line. On the other hand, in the second region 106, a polysilicon conductive pattern/line may function as a passive device such as a resistor or serving as a dummy pattern adapted to be used, for example, for etching compensation, lithography process, chemical mechanical polishing (CMP) process or thermal treatment.

In this embodiment, the portion 112 of the substrate 100 where the dummy stress patterns 114 are disposed in the first region 104 is a virtual partition band dividing two large active stress portions apart, and a series of dummy stress patterns 114 are formed along the partition band. In addition, a dummy opening 114a may be created within the active stress pattern 110a on an isolation structure between the active regions 108a, serving as a part of the dummy stress portion for releasing undue stress in the active stress pattern 110a.

The active stress patterns 110 used in this embodiment can be tensile stress patterns or compressive stress patterns, depending on the types of the active devices in the active regions 108a and 108b. The material of the stress patterns 110 is, for example, silicon nitride or any doped or cured silicon nitride. The term “dummy” used herein indicates that the area where the stress patterns are applied does not really require additional stress. The material of the dummy stress pattern 114, for example, can also be silicon nitride or any doped or cured silicon nitride. The presence of the dummy stress patterns are just for releasing undue stress possibly generated due to the presence of the active stress patterns. Likewise, the dummy stress patterns 114 can also be dummy tensile stress patterns or dummy compressive stress patterns, depending on the types of the active devices in the active regions 108a and 108b. The dummy stress patterns 114 and the stress patterns 110 may be formed in the same process. The dummy stress patterns 114, for example, occupies 1%-99% of the total area of the substrate 100.

Another embodiment is now described with reference to FIG. 3. In this embodiment, a stress layer structure 202 is applied onto a substrate 200 according to the present invention. The stress layer structure 202 includes an active stress portion for raising stress, and a dummy stress portion for releasing undue stress as an effect of balance. The active stress portion includes a continuous stress pattern 210 covering active regions 208a and 208b in a first region 204 which require stress, and the dummy stress portion includes dummy stress patterns disposed on a portion of the substrate 200 in the first region 204, where no circuit element is formed, as well as a portion of the substrate 200 in a second region 206. It is to be noted that in this embodiment, the dummy stress patterns are implemented with a series of dummy openings 214b created in the continuous active stress pattern 210 so as to expose blocks of the substrate as a virtual partition band in the first region 204 as well as at corners of the continuous active stress pattern 210, and implemented with a continuous dummy stress layer 214c with dummy openings created therein in the second region 206. For example, the dummy openings in the continuous dummy stress layer 214c are created to partially or completely expose specified structures, e.g. polysilicon conductive patterns/lines 216, 218 and 220, in the second region 206. In addition, dummy openings 214a may be created in the active stress pattern 210 between the active regions 208a, serving as a part of the dummy stress portion for releasing undue stress in the active stress pattern 210. On the substrate in both of the first and second regions 204 and 206, a variety of polysilicon patterns/lines are formed. For example, in the first region 204, an active device such as a MOS transistor is formed in an active region covered with a polysilicon pattern/line. On the other hand, in the second region 206, a polysilicon conductive pattern/line may function as a passive device such as a resistor or serving as a dummy pattern adapted to be used, for example, for etching compensation, lithography process, chemical mechanical polishing (CMP) process or thermal treatment.

Similar to the first embodiment described above, the active stress patterns 210 used in this embodiment can be tensile stress patterns or compressive stress patterns, depending on the types of the active devices in the active regions 208a and 208b. The material of the stress patterns 210 is, for example, silicon nitride. The material of the continuous dummy stress layer 214c, for example, can also be silicon nitride or any doped or cured silicon nitride. The continuous dummy stress layer 214c can also be dummy tensile stress patterns or dummy compressive stress patterns, depending on the types of the active devices in the active regions 208a and 208b. The dummy stress patterns 214a˜c and the stress patterns 210 may be formed in the same process. The dummy stress patterns 214a˜c, for example, occupies 1%˜99% of the total area of the substrate 100.

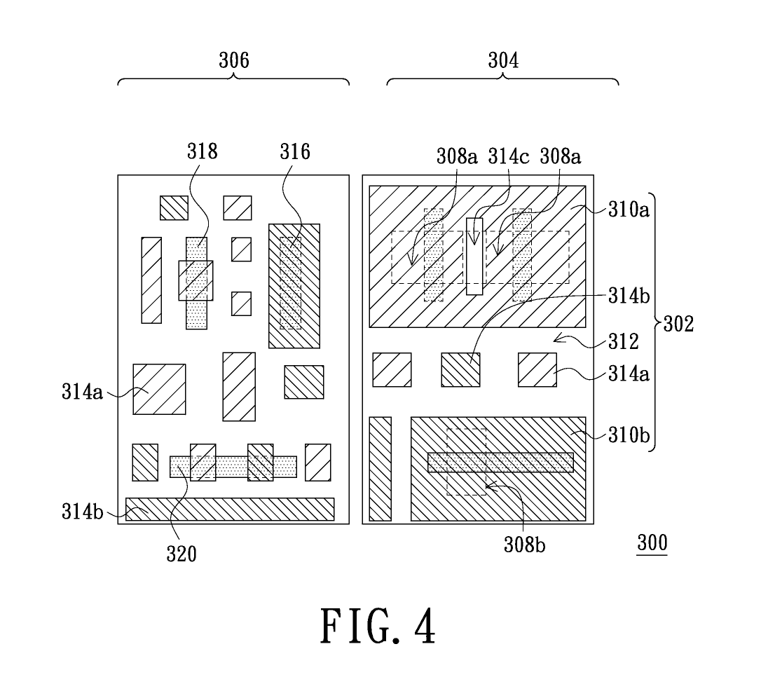

FIG. 4 is a top view schematically illustrating the configuration of a stress layer structure according to a third embodiment of the present invention. This tensile stress material and compressive stress material are used. The stress layer structure 302 includes an active stress portion for raising stress, and a dummy stress portion for releasing undue stress as an effect of balance. The active stress portion includes tensile stress patterns 310a and compressive stress patterns 310b respectively covering active regions 308a and 308b in a first region 304, which require stress, and the dummy stress portion includes dummy tensile stress patterns 314a and dummy compressive stress patterns 314b alternately covering a portion 312 of the substrate 300 in the first region 304, where no circuit element is formed, as well as a portion of the substrate 300 in a second region 306. Furthermore, the dummy stress patterns 314a and 314b may further partially or completely cover specified structures, e.g. polysilicon conductive lines 316, 318 and 320, in the second region 306. On the substrate in both of the first and second regions 304 and 306, a variety of polysilicon patterns/lines are formed. For example, in the first region 304, an active device such as a MOS transistor is formed in an active region covered with a polysilicon pattern/line. On the other hand, in the second region 306, a polysilicon conductive pattern/line may function as a passive device such as a resistor or serving as a dummy pattern adapted to be used, for example, for etching compensation, lithography process, chemical mechanical polishing (CMP) process or thermal treatment.

In this embodiment, the portion 312 of the substrate 300 where the dummy stress patterns 314a and 314b are disposed in the first region 304 is a virtual partition band dividing active regions 308a and active region 308b, and a series of dummy stress patterns 314a and 314b are formed along the partition band. In addition, a dummy opening 314c may be created within the active stress pattern 310a on an isolation structure between active regions 308a, serving as a part of the dummy stress portion for releasing undue stress in the active stress pattern 310a.

With the application of dummy stress layers and/or creation of dummy openings as dummy stress patterns, undue stress can be released so as to prevent the stress layer from the damage of producing particles caused by the stress layer cracking or peeling off, thereby improving yield of products.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A stress layer structure formed on a substrate, the substrate including a first region where active devices are formed and a second region where passive devices are formed, the stress layer structure comprising:
an active stress portion formed of a stress material and disposed on the substrate, the active stress portion including first and second active stress patterns in the first region, which cover at least a first active region and a second active region, respectively, and are separated from each other; and
a dummy stress portion formed of a stress material and disposed on the substrate, the dummy stress portion including at least one first dummy stress pattern in the first region, which is formed directly on the substrate and disposed between and separated from the first and second active stress patterns.

2. The stress layer structure of claim 1, wherein the stress material of the active stress portion is silicon nitride.

3. The stress layer structure of claim 1, wherein the stress material of the dummy stress portion is silicon nitride, doped silicon nitride or cured silicon nitride.

4. The stress layer structure of claim 1, wherein the dummy stress portion further includes a second dummy stress pattern in the second region, which is formed directly on the substrate.

5. The stress layer structure of claim 1, wherein the dummy stress portion further includes a third dummy stress pattern in the second region, which covers a polysilicon conductive pattern/line.

6. The stress layer structure of claim 1, wherein the dummy stress portion further includes a dummy opening in the first region, which is created in the first active stress pattern.

7. The stress layer structure of claim 1, wherein the first and second active stress patterns are both tensile stress patterns or both compressive stress patterns.

8. The stress layer structure of claim 1, wherein the first and second active stress patterns are a tensile stress pattern and a compressive stress pattern.

9. The stress layer structure of claim 1, wherein the dummy stress portion further includes a plurality of dummy stress patterns in the second region, which are all tensile stress patterns or all compressive stress patterns formed directly on the substrate.

10. The stress layer structure of claim 1, wherein the dummy stress portion further includes a plurality of dummy stress patterns in the second region, which include at least one tensile stress pattern and at least one compressive stress pattern formed directly on the substrate.

11. The stress layer structure of claim 1, wherein the dummy stress portion further includes a plurality of dummy stress patterns in the second region, which are all tensile stress patterns or all compressive stress patterns covering a plurality of polysilicon conductive patterns/lines.

12. The stress layer structure of claim 1, wherein the dummy stress portion further includes a plurality of dummy stress patterns in the second region, which include at least one tensile stress pattern and at least one compressive stress pattern covering a plurality of polysilicon conductive patterns/lines.

13. The stress layer structure of claim 1, wherein the dummy stress portion occupies 1%˜99% of the total area of the substrate.

14. The stress layer structure of claim 1, wherein the dummy stress portion includes more than one of the first dummy stress pattern in the first region, which are allocated in series along a virtual partition band dividing the first and second active stress patterns apart.

15. A stress layer structure formed on a substrate, the substrate including a first region where active devices are formed and a second region where passive devices are formed, the stress layer structure comprising:
an active stress portion formed of a stress material and disposed on the substrate, the active stress portion including a continuous active stress pattern in the first region, which covers at least one active region; and
a dummy stress portion formed of a stress material and disposed on the substrate, the dummy stress portion including a continuous dummy stress pattern with a plurality of dummy openings therein in the second region.

16. The stress layer structure of claim 15, wherein the stress material of the active stress portion is silicon nitride, doped silicon nitride or cured silicon nitride.

17. The stress layer structure of claim 15, wherein the stress material of the dummy stress portion is silicon nitride, doped silicon nitride or cured silicon nitride.

18. The stress layer structure of claim 15, wherein the continuous active stress pattern in the first region covers a first active region and a second active region, and the dummy stress portion further includes a plurality of dummy openings in the first region, which are created in the continuous active stress pattern and disposed between the first and second active regions, and from which essentially the substrate is exposed.

19. The stress layer structure of claim 18, wherein the plurality of dummy openings in the first region are allocated in series along a virtual partition band dividing the first and second active regions apart.

20. The stress layer structure of claim 15, wherein the dummy stress portion further includes a plurality of dummy openings in the second region, which are created in the continuous dummy stress pattern, and from which essentially the substrate is exposed.

21. The stress layer structure of claim 15, wherein the dummy stress portion further includes a plurality of dummy openings in the second region, which are created in the continuous dummy stress pattern, and from which a plurality of polysilicon conductive patterns/lines are exposed.
